(19) United States
(12) Patent Application Publication
(10) Pub. No.: US 2025/0381679 A1
(43) Pub. Date: Dec. 18, 2025

(54) ROBOT HAND, SUBSTRATE CONVEYANCE APPARATUS, AND HOLDING UNIT

(71) Applicant: HIRATA CORPORATION, Kumamoto (JP)

(72) Inventors: Bungo MATSUMOTO, Kumamoto (JP); Yuki HAMASAKI, Kumamoto (JP)

(73) Assignee: HIRATA CORPORATION, Kumamoto (JP)

(21) Appl. No.: 18/877,257

(22) PCT Filed: Oct. 17, 2022
(86) PCT No.: PCT/JP2022/038518

§ 371 Date: Dec. 19, 2024

(51) Int. Cl. B25J 15/00; B25J 9/00

(52) U.S. Cl. CPC B25J 15/0014; B25J 9/0009

(57) ABSTRACT

A robot hand includes: a hand member holding a substrate; a support part disposed at the hand member and supporting a lower surface of the substrate; and a first driving part disposed at the hand member and driving the support part. The first driving part moves the support part between a forward position higher than an upper surface of the hand member and a backward position lower than the forward position. The forward position is set to a position that is away from the upper surface of the hand member by more than a maximum warpage amount expected for the substrate.

### TECHNICAL FIELD

The present invention relates to a robot hand, a substrate conveyance apparatus, a holding unit, and a substrate removal method.

### RELATED ART

Conventionally, in the art of manufacturing semiconductor and the like, the following technique has been provided: an industrial substrate conveyance robot is used to remove a substrate (e.g., a wafer, a glass substrate, etc.) from a container accommodating the substrate and convey the substrate to various processing apparatuses to perform processings on the conveyed substrate. Specifically, the industrial substrate conveyance robot includes a robot arm and a robot hand attached to a tip of the robot arm, and the conveyed substrate is held by the robot hand. For example, as a method for conveying a substrate by the industrial substrate conveyance robot, various techniques have been disclosed relating to a substrate removal method in which a robot hand abuts against a substrate from a front end or a rear end of the substrate, or the robot hand supports the substrate from below the substrate, and accordingly lifts the substrate from a substrate support part in a container and removes the substrate from the container along with movement of the robot arm.

### RELATED ART DOCUMENTS

### Patent Documents

Patent Document 1: Japanese Patent No. 6752061

### SUMMARY OF INVENTION

### Problems to Be Solved by Invention

In recent years, in the art of semiconductor devices, while an integration density of devices has been increasing, miniaturization of devices has also been progressing. Along with this, a method called panel level packaging (hereinafter referred to as PLP) has become widespread as a packaging technique for devices with a high integration density. PLP is a method for manufacturing multiple semiconductor packages collectively by arranging numerous chips on a rectangular panel, and various industrial robots are used in a production line of semiconductor packages involving PLP. PLP includes processes such as coating (sealing), with resin, an upper surface of a panel on which numerous chips are placed, and there is a problem that a panel handled in the production line of semiconductor packages involving PLP is prone to significant warpage (upward warpage and downward warpage) in an up-down direction.

In a FOUP (Front Opening Unified Pod), which is an accommodating container for substrates, support parts (hereinafter referred to as slots) for substrates are formed at equal intervals, and each slot spacing has become a narrow pitch to improve storage efficiency of substrates. When removing a substrate from the FOUP using a substrate conveyance robot, the robot hand is inserted into the FOUP. However, in addition to narrowness of the pitch between the slots in the FOUP, in the case where upward warpage or downward warpage occurs at the substrate, the gap for inserting the robot hand between the slots becomes non-uniform, so there is a risk that the robot hand may come into contact with the substrate during insertion of the robot hand at sites where the gap is narrow. Further, on a lower surface of a substrate used in PLP. areas where contact with the robot hand is allowed are predetermined. To suppress adhesion of particles onto the substrate due to contact between the robot hand and the substrate, the robot hand is required to support the substrate with a minimized contact area with the substrate using support members such as support pins in such areas. Additionally, the robot hand is required to support the substrate such that the lower surface of the substrate does not touch a hand member of the robot hand to be described later, regardless of a form of warpage of the substrate. Further, since the robot hand handles heavy objects such as substrates with chips mounted thereon, the robot hand is required to have a sufficient rigidity.

Based on the above, the structure of the robot hand is a structure also capable of being inserted into sites with a narrow gap, and is a structure capable of accommodating a support member inside the robot hand and causing the support member to protrude from an upper surface of the robot hand after the robot hand is inserted into a container, and further, is required to cause the support member to protrude by more than a warpage amount of the substrate to reliably support the substrate.

Thus, the present invention provides a robot hand that is applied to handling a substrate accommodated in a container with a narrow slot pitch and is capable of addressing warpage occurring at the substrate, a substrate conveyance apparatus to which a substrate conveyance robot including the above robot hand is attached, a holding unit attached to the robot hand, and a substrate removal method for removing a substrate using the above robot hand.

### Means for Solving Problems

To achieve the above objective, according to the present invention, a robot hand is provided, including: a hand member holding a substrate; a support part disposed at the hand member and supporting a lower surface of the substrate; and a first driving part disposed at the hand member and driving the support part. The first driving part moves the support part between a forward position higher than an upper surface of the hand member and a backward position lower than the forward position. The forward position is set to a position that is away from the upper surface of the hand member by more than a maximum warpage amount expected for the substrate.

To achieve the above objective, according to the present invention, a substrate conveyance apparatus is provided, including: a substrate conveyance robot including the above robot hand; a substrate conveyance module inside which the substrate conveyance robot is provided; a detection part detecting relative positions between the robot hand and the substrate; and a control part driving and moving the support part. Based on a detection result of the detection part, the control part starts control of the first driving part of the robot hand to drive the support part.

To achieve the above objective, according to the present invention, a holding unit is provided. The holding unit is attached to a hand member of a robot hand having an upper surface provided with a recess and holds a substrate. The holding unit includes: a base part disposed on a bottom surface of the recess of the hand member and having an accommodating opening defined by a sidewall; a support part disposed at the base part and supporting a lower surface of the substrate; and a first transmission mechanism disposed at the base part and connected to the support part. The base part is configured in a frame shape with the accommodating opening, and a thickness of the base part is smaller than a distance between the upper surface of the hand member and the bottom surface of the recess. The support part is located in the accommodating opening surrounded by the sidewall. The first transmission mechanism drives the support part by a driving force of a driving source to move the support part between a raising position higher than the upper surface of the hand member and a lowering position lower than the upper surface of the hand member. The raising position is set to a position that is away from the upper surface of the hand member by more than a maximum warpage amount expected for the substrate.

To achieve the above objective, according to the present invention, a substrate removal method is provided. The substrate removal method serves for removing a substrate, which is supported by a substrate support part of a container, by a robot hand provided at a substrate conveyance robot. The robot hand is attached to an arm part of the substrate conveyance robot capable of extending, retracting, and rotating within a horizontal plane and also capable of rising and lowering in an up-down direction, and includes a hand member holding the substrate, a support part disposed at the hand member, and a first driving part disposed at the hand member to drive movement of the support part. The substrate removal method includes: an insertion process of inserting the robot hand to below the substrate; a support part moving process of moving the support part and supporting a lower surface of the substrate; and a removal process of moving the robot hand and removing the substrate from the substrate support part. The insertion process is executed with the support part located at a backward position lower than an upper surface of the hand member. In the support part moving process, according to driving of the first driving part, the support part is moved from the backward position to a forward position set to a position that is higher than the upper surface of the hand member and is away from the upper surface of the hand member by more than a maximum warpage amount expected for the substrate.

### Effects of Invention

According to the present invention, it is possible to provide a robot hand, a substrate conveyance apparatus, a holding unit, and a substrate removal method in which, when removing a substrate with a large warpage accommodated in a container with a narrow slot pitch using the robot hand, the robot hand is inserted into the container, but contact between the robot hand and the substrate is prevented during the insertion, and the substrate with a large warpage can be held and removed while preventing contact with the robot hand.

### BRIEF DESCRIPTION OF DRAWINGS

FIG. 1 is a perspective view illustrating a robot hand according to an embodiment of the present invention.

FIG. 2 is a perspective view illustrating the robot hand shown in FIG. 1 with a top cover of a hand member removed.

FIG. 3 is a perspective view illustrating the robot hand shown in FIG. 1 attached to a substrate conveyance robot.

FIG. 4 is a perspective view illustrating a holding unit when a support part and a first restriction part of the robot hand shown in FIG. 1 are located at a forward position.

FIG. 5 is a perspective view illustrating the holding unit when the support part and the first restriction part of the robot hand shown in FIG. 1 are located at a backward position.

FIG. 6 is a side view illustrating the holding unit when the support part and the first restriction part shown in FIG. 4 are located at the forward position.

FIG. 7 is a side view illustrating the holding unit when the support part and the first restriction part shown in FIG. 5 are located at the backward position.

FIG. 8 is a perspective view illustrating another holding unit when the support part of the robot hand shown in FIG. 1 is located at the forward position.

FIG. 9 is a top view illustrating a displacement support mechanism displacing a third support part of the robot hand shown in FIG. 1.

FIG. 10 is a side view illustrating a state in which the support part of the robot hand shown in FIG. 1 is located at the forward position to hold a substrate at which warpage occurs.

FIG. 11 is a side view illustrating the substrate at which warpage occurs shown in FIG. 10.

FIG. 12 is a perspective view showing a substrate conveyance apparatus according to the present invention.

FIG. 13 is a structural arrangement view illustrating the substrate conveyance apparatus shown in FIG. 12.

FIG. 14 is a view illustrating a container accommodating substrates to which the robot hand of FIG. 1 and the substrate conveyance apparatus of FIG. 12 are applied.

FIG. 15 is a flowchart of a substrate removal method to which the robot hand of FIG. 1 and the substrate conveyance apparatus of FIG. 12 are applied.

FIG. 16 is a side view illustrating a first state of the robot hand of FIG. 1 corresponding to a step in the flowchart of the substrate removal method of FIG. 15.

FIG. 17 is a side view illustrating a second state of the robot hand of FIG. 1 corresponding to a step in the flowchart of the substrate removal method of FIG. 15.

FIG. 18 is a side view illustrating a third state of the robot hand of FIG. 1 corresponding to a step in the flowchart of the substrate removal method of FIG. 15.

FIG. 19 is a side view illustrating a fourth state of the robot hand of FIG. 1 corresponding to a step in the flowchart of the substrate removal method of FIG. 15.

### DESCRIPTION OF EMBODIMENTS

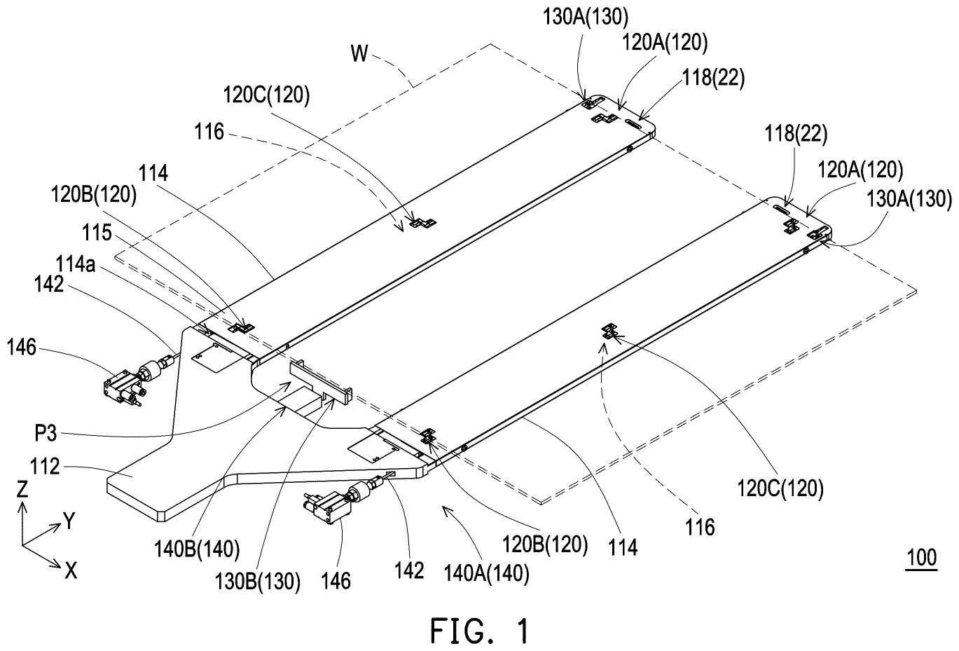

Herein, referring to exemplary embodiments of the present invention in detail, examples of the exemplary embodiments are shown in the accompanying drawings. In the following. combining FIG. 1 to FIG. 19, a robot hand 100 of this embodiment, a substrate conveyance apparatus 20 to which a substrate conveyance robot 30 including the robot hand 100 is attached, a holding unit 200 attached to the robot hand 100, and a flow of a substrate removal method for removing a substrate W using the robot hand 100 will be described, with a spatial coordinate system XYZ taken as a left-right direction X, a front-rear direction Y, and an up-down direction Z, but this is merely an example of the present invention and the present invention is not limited thereto.

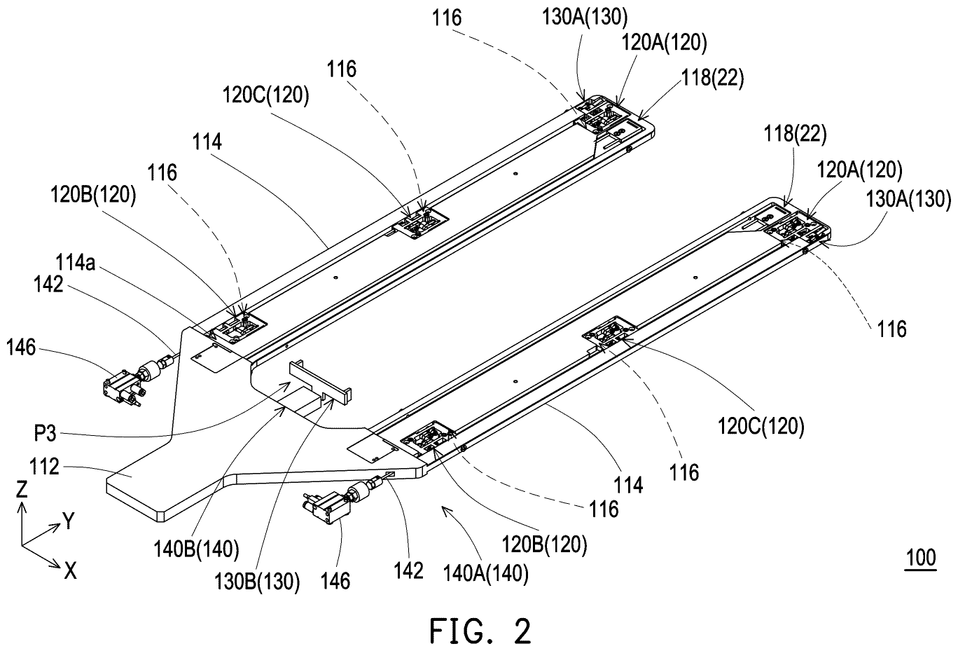

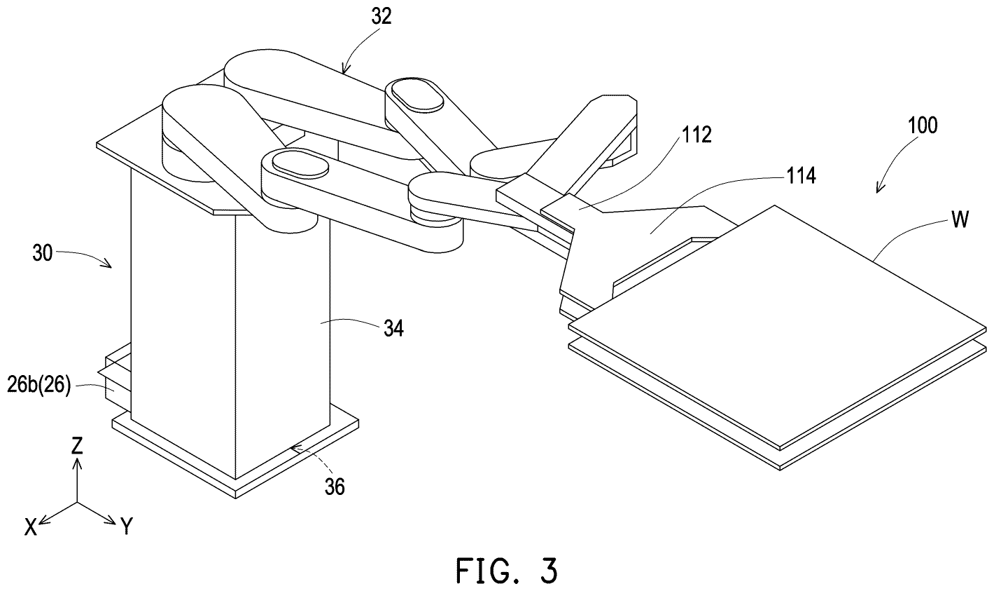

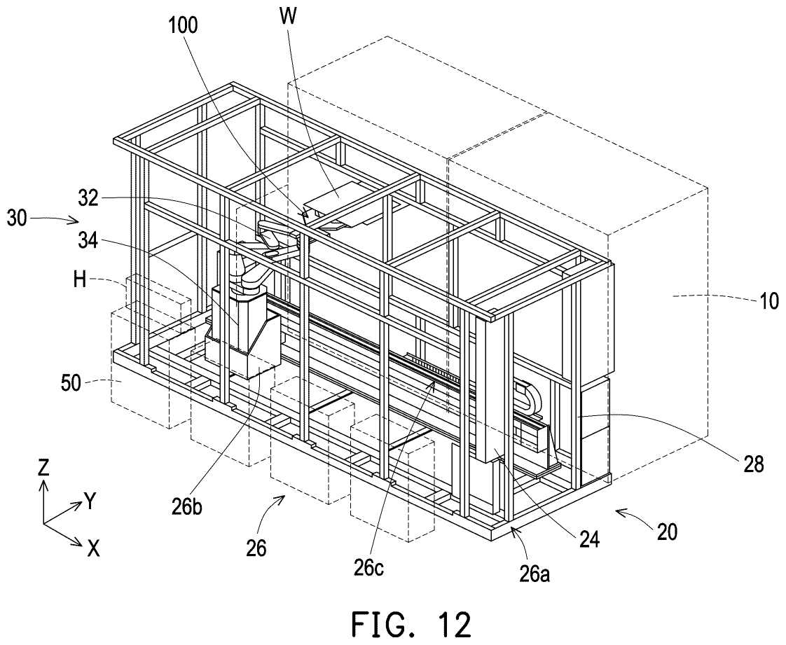

In this embodiment, the robot hand 100 (shown in FIG. 1 and FIG. 2) is attached to the substrate conveyance robot 30 (shown in FIG. 3), which conveys the substrate W, to hold the substrate W. The robot hand 100 includes a base 112, a hand member 114, a support part 120, a restriction part 130, and a driving part 140. The substrate conveyance robot 30 is, for example, a moving robot capable of being attached to the substrate conveyance apparatus 20 (shown in FIG. 12) to be described later, and the robot hand 100 is, for example, a robot hand attached to an arm part 32 of the substrate conveyance robot 30 to hold the substrate W that is conveyed according to movement of the arm part 32. As an example, the support part 120 includes a first support part 120A, a second support part 120B, and a third support part 120C; the restriction part 130 includes a first restriction part 130A and a second restriction part 130B; and the driving part 140 includes a first driving part 140A and a second driving part 140B, but the present invention is not limited thereto.

Specifically, the robot hand 100 includes a base 112 connected to the arm part 32 and a hand member 114 extending from the base 112 to hold the substrate W, and is configured in a substantially Y-shape. The support part 120 is disposed at the hand member 114 and supports a lower surface of the substrate W. Further, multiple support parts 120 are disposed at the hand member 114, including a first support part 120A disposed on a tip side of the hand member 114, a second support part 120B disposed on a base end side, which is the base 112 side, of the hand member 114, and a third support part 120C disposed between the first support part 120A and the second support part 120B in an extending direction (e.g., the front-rear direction Y) of the hand member 114. The first restriction part 130A is disposed on the tip side of the hand member 114 and is opposed to or abuts against a front end surface of the substrate W. The second restriction part 130B is disposed on the base end side, which is the base 112 side, of the hand member 114 and is opposed to or abuts against a rear end surface of the substrate W.

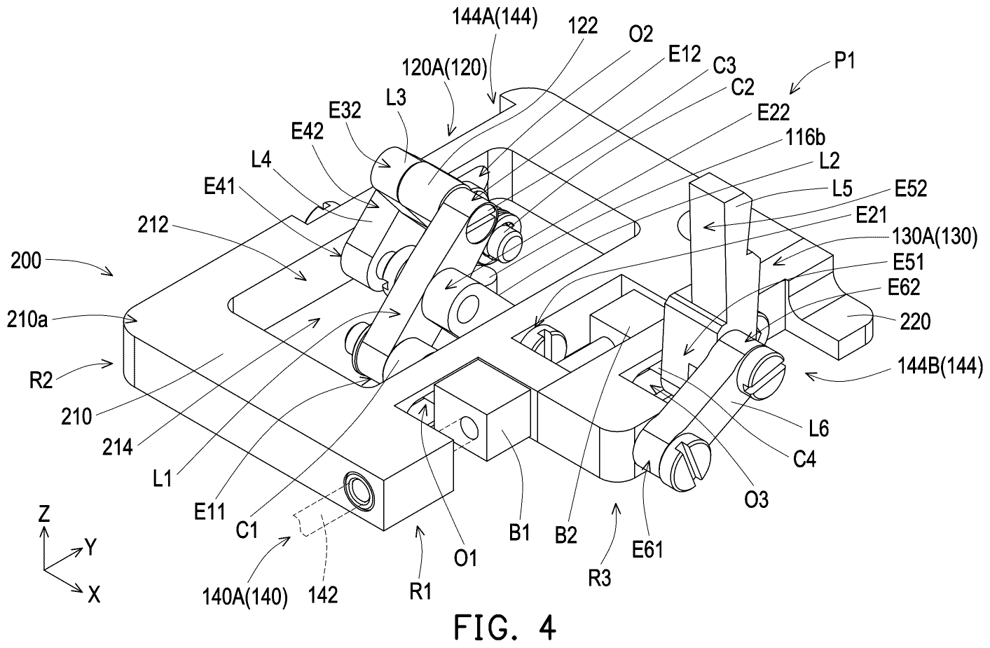

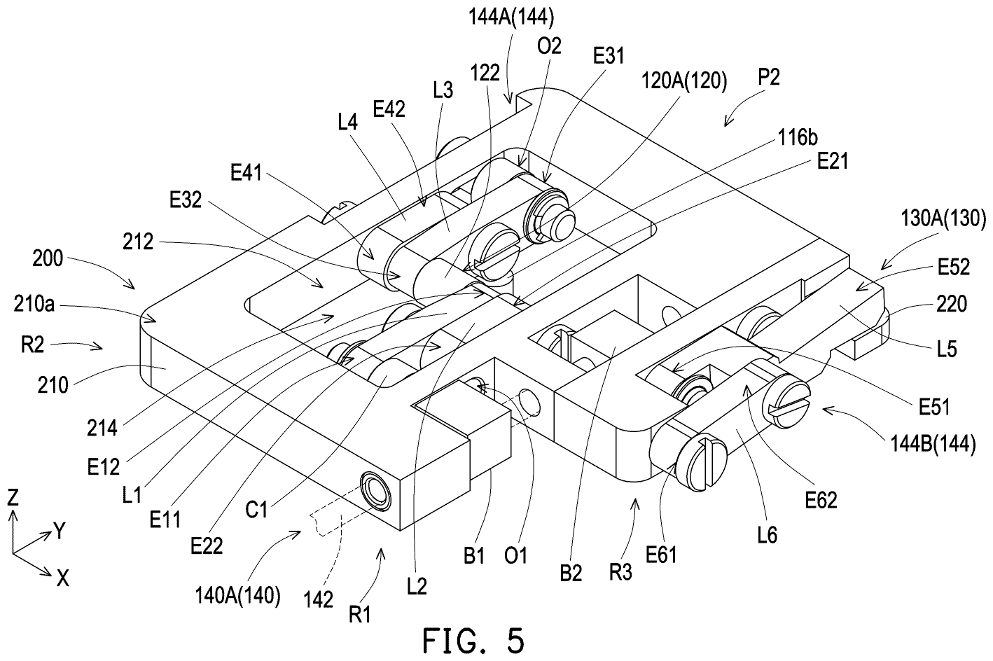

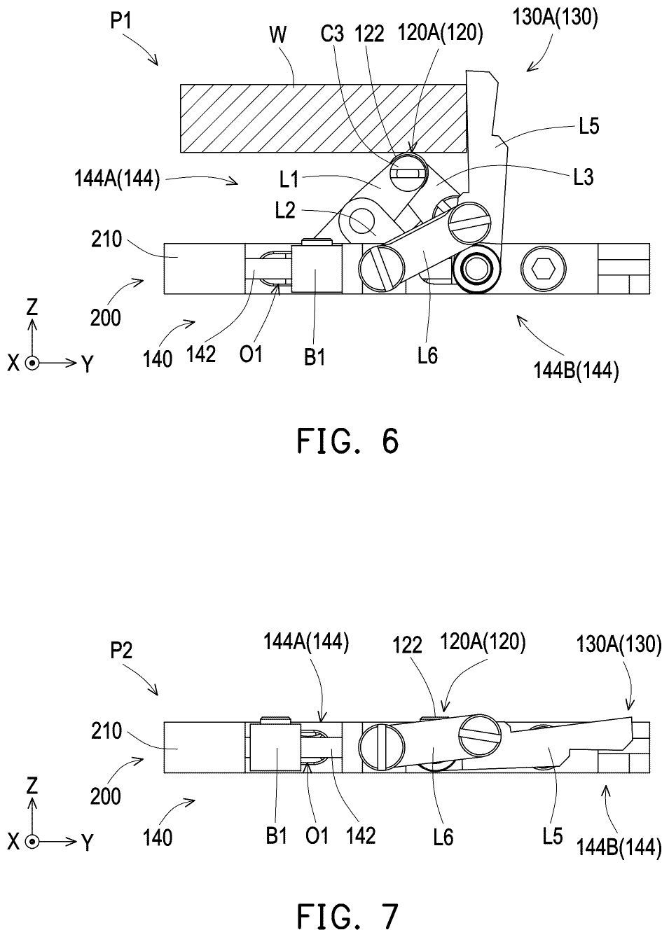

Furthermore, the first driving part 140A is disposed at the hand member 114 and drives the support part 120 and the first restriction part 130A. The support part 120 and the first restriction part 130A move in the up-down direction Z. Specifically, the support part 120 moves in the up-down direction Z while undergoing a pivoting action by a pivoting mechanism (a first transmission mechanism 144A to be described later). Thus, the support part 120 supports the lower surface of the substrate W to lift the lower surface of the substrate W upward in the up-down direction Z. Further, a movement amount of the support part 120 in the up-down direction Z is set to be larger than a maximum warpage amount expected for the substrate W. The first restriction part 130A moves in the up-down direction Z while undergoing a pivoting action by a pivoting mechanism (a second transmission mechanism 144B to be described later). Thus, the first restriction part 130A may also be opposed to the front end surface of the substrate W in a substantially perpendicular direction, or abut against the front end surface of the substrate W in a manner approaching from a substantially perpendicular direction. The first driving part 140A integrally moves the support part 120 and the first restriction part 130A between a forward position P1 (e.g., a state shown in subsequent FIG. 4 and FIG. 6) higher than an upper surface 114a of the hand member 114 and a backward position P2 (e.g., a state shown in subsequent FIG. 5 and FIG. 7) lower than the forward position P1. The forward position P1 is, for example, a position at which the support part 120 and the first restriction part 130A are capable of protruding from the upper surface 114a of the hand member 114 to lift and hold the substrate W. Further, with respect to the support part 120 for supporting the lower surface of the substrate W, the forward position P1 is set to a position that is away from the upper surface 114a of the hand member 114 by more than the maximum warpage amount expected for the substrate W (details will be described later). The backward position P2 is, for example, a position at which the support part 120 and the first restriction part 130A are retracted into the hand member 114 and are away from the substrate W.

Herein, preferably, as shown in FIG. 2, recesses 116 are provided on the upper surface 114a of the hand member 114, and the support part 120 and the first restriction part 130A are disposed in the recesses 116. Accordingly, since the support part 120 and the first restriction part 130A at the backward position P2 are accommodated in the recesses 116, the hand member 114 can be configured to be thin. Further, preferably, as shown in FIG. 1, a top cover 115 for covering the recesses 116 is disposed on the upper surface 114a of the hand member 114, but the present invention is not limited thereto. Furthermore, as shown in FIG. 1, a reflective sensor 118 is provided on the tip side of the hand member 114. The reflective sensor 118 functions as a detection part 22 to be described later and is capable of detecting the front end surface of the substrate W, but the present invention is not limited thereto.

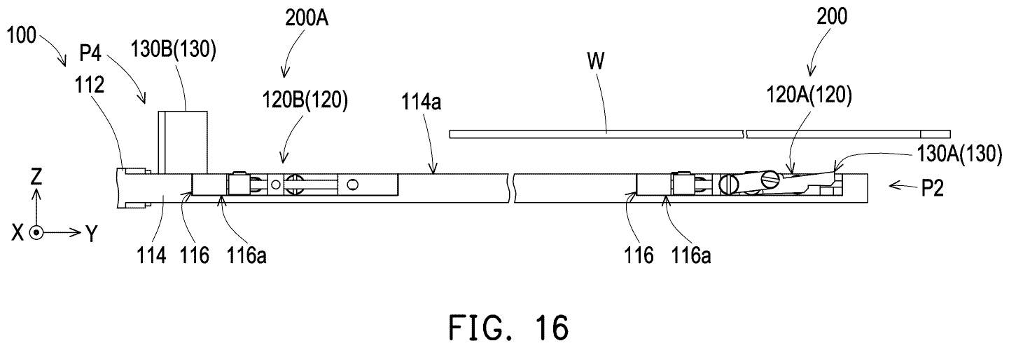

Further, the second driving part 140B is disposed at the hand member 114 and drives the second restriction part 130B. The second restriction part 130B moves in the front-rear direction Y. As an example, as shown in FIG. 1 and FIG. 2, one second driving part 140B is provided between a central portion of the hand member 114 and the second restriction part 130B. However, in another embodiment (not shown), a pair of second driving parts 140B may be provided on both sides of the hand member 114 and located on both left and right sides of the second restriction part 130B. Specifically, the second restriction part 130B abuts against the rear end surface of the substrate W in a manner approaching from a perpendicular direction. The second driving part 140B moves the second restriction part 130B between an advance position P3 (e.g., a state shown in FIG. 1) abutting against the rear end surface of the substrate W and a retreat position P4 (a position closer to the base 112 than the state in FIG. 1) on the base end side of the advance position P3. The advance position P3 is, for example, a position at which the second restriction part 130B abuts against the rear end surface of the substrate W and is capable of clamping the front and rear end surfaces of the substrate W together with the first restriction part 130A, but the present invention is not limited thereto. The retreat position P4 is, for example, a position at which the second restriction part 130B retreats away from the substrate W. The advance position P3 and the retreat position P4 are also shown in FIG. 16 to FIG. 19.

In other words, as an example, multiple support parts 120 and the first restriction part 130A are driven via the first driving part 140A, and the second restriction part 130B is driven via the second driving part 140B. The purpose of driving the support part 120 and the first restriction part 130A by the same driving part (i.e., the first driving part 140A) is to move the support part 120 and the first restriction part 130A integrally. When not in use for holding the substrate W, with the support part 120 and the first restriction part 130A integrally moved to the backward position P2 and accommodated in the recesses 116, the robot hand 100 can be configured to be thin. Thus, the robot hand 100 can easily move to below the substrate W. Further, when in use for holding the substrate W, with the support part 120 and the first restriction part 130A integrally moving to the forward position P1, the substrate W can be held simultaneously by the support part 120 and the first restriction part 130A. Accordingly, the robot hand 100 can apply to holding a substrate W accommodated in a container with a narrow pitch.

In contrast, in this embodiment, the purpose of driving the first restriction part 130A and the second restriction part 130B by different driving parts (i.e., the first driving part 140A and the second driving part 140B) is to drive movements of the first restriction part 130A and the second restriction part 130B at different timings. First, the first restriction part 130A, which moves in the up-down direction Z while undergoing a pivoting action, is moved from the backward position P2 to the forward position P1 opposed to the front end surface of the substrate W in the front-rear direction Y. Next, the second restriction part 130B, which moves in the front-rear direction Y, is moved from the retreat position P4 to the advance position P3 abutting against the rear end surface of the substrate W. With the second restriction part 130B moving from the retreat position P4 toward the advance position P3, the substrate W is pressed to a position abutting against the first restriction part 130A. Since the first restriction part 130A and the second restriction part 130B can reliably abut against the front end surface and the rear end surface of the substrate W, holding stability of the substrate W is improved.

However, in another embodiment (not shown), the robot hand 100 may also integrally move the first support part 120A and the first restriction part 130A, which are disposed adjacent to each other, by different driving parts, or move the first support part 120A and the first restriction part 130A at different timings by the same first driving part 140A or different driving parts. The present invention is not limited thereto. Further, the robot hand 100 may also be configured such that only the first support part 120A and the first restriction part 130A disposed adjacent to each other move integrally by driving of the first driving part 140A, and the second support part 120B and the third support part 120C are moved by driving of a separate driving part. The present invention is not limited to integrally moving multiple support parts 120 by the same first driving part 140A. Further, the robot hand 100 may also simultaneously drive movements of multiple support parts 120 and multiple restriction parts 130 using one driving part. The present invention is not limited to the case where all of the multiple support parts 120 in the robot hand 100 are driven by the first driving part 140A to move integrally with the first restriction part 130A, nor limited to the case where the multiple restriction parts 130 cannot move integrally. Quantities, positions, and connection relationships of the support parts 120, the restriction parts 130, and the driving parts 140 may be adjusted as necessary.

Further, in another embodiment (not shown), it is also possible that the first restriction part 130A and the second restriction part 130B of the robot hand 100 do not abut against the end surfaces of the substrate. In other words, at the forward position P1, the first restriction part 130A may be opposed to the front end surface of the substrate W with a gap therebetween, and at the advance position P3, the second restriction part 130B may be opposed to the rear end surface of the substrate W with a gap therebetween. In that case, during conveyance of the substrate W, by restricting excessive movement of the substrate W in the front-rear direction Y. the first restriction part 130A and the second restriction part 130B suppress fall-off of the substrate W from the robot hand 100. Further, although the gaps between the first restriction part 130A, the second restriction part 130B, and the front and rear end surfaces of the substrate W depend on a size of an area in which contact with the robot hand 100 is allowed on the lower surface of the substrate W, a gap of about 1 mm is desirable, for example. Further, as an example, it is also possible that the robot hand 100 does not include the restriction part 130. In such an embodiment, the first driving part 140A drives the support part 120.

Further, in this embodiment, multiple support parts 120 located symmetrically are provided respectively at the hand member 114 of the robot hand 100 and stably support the substrate W. The recess 116 is provided at the hand member 114, and may be an elongated groove extending along an extending direction Y of the hand member 114, or may be multiple rectangular grooves provided and distributed along the extending direction Y of the hand member 114. The purpose of providing multiple support parts 120 at the hand member 114 is to support the lower surface of the substrate W by the first support part 120A from the tip side of the hand member 114, by the second support part 120B from the base end side of the hand member 114, and by the third support part 120C from a middle of the hand member 114.

However, in another embodiment (not shown), it is also possible that, in the robot hand 100, the first support part 120A corresponding to the tip side and the second support part 120B corresponding to the base end side are disposed, with the third support part 120C corresponding to the middle omitted; alternatively, only one of the first support part 120A, the second support part 120B, and the third support part 120C is disposed, or four or more support parts 120 are disposed. Further, the robot hand 100 is not limited to being disposed as a combination of the base 112 and the hand member 114 and may include one hand member configured as a rectangular plate part, and the support part 120 may be disposed at predetermined positions on an upper surface of the plate part as necessary. Further, in the case where three support parts 120 corresponding to three portions of the tip side, the base end side, and the middle are provided, the third support part 120C is not limited to being located exactly at a center between the first support part 120A and the second support part 120B. The position of the third support part 120C may be configured closer to the first support part 120A or closer to the second support part 120B according to conditions such as a position at which warpage or deflection occurs at the substrate W applied.

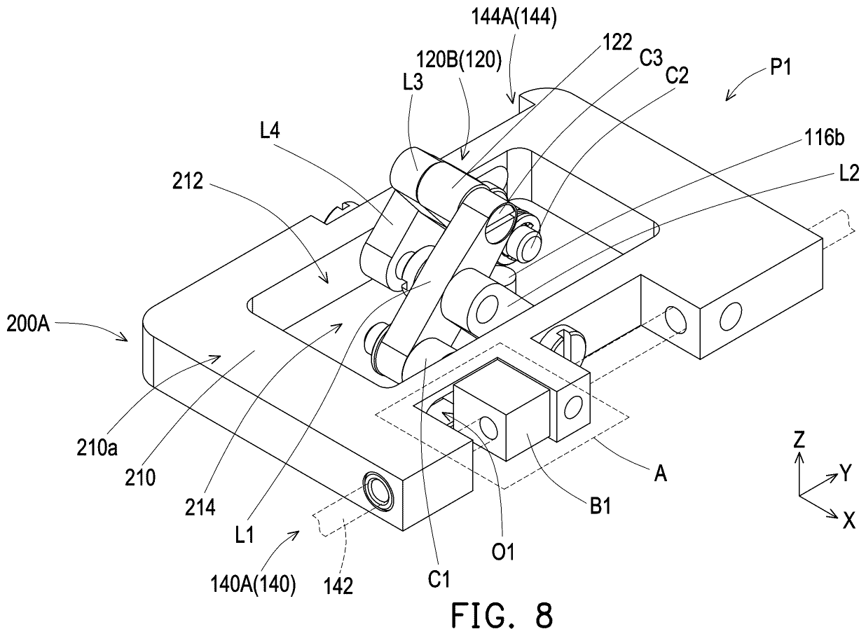

Further, as shown in FIG. 1, FIG. 4, and FIG. 5, the first driving part 140A includes a driving shaft 142, a transmission mechanism 144, and a driving source 146 for driving movement of the driving shaft 142. The driving shaft 142 is, for example, inserted and disposed inside the hand member 114 along the extending direction Y, and moves along the extending direction Y between the tip side and the base end side of the hand member 114. The transmission mechanism 144 causes the support part 120 and the first restriction part 130A to move in conjunction with the driving shaft 142. The transmission mechanism 144 integrally moves the support part 120 (e.g., the first support part 120A) and the first restriction part 130A between the forward position P1 and the backward position P2. The second support part 120B and the third support part 120C may also move integrally in conjunction with the driving shaft 142 via corresponding transmission mechanisms 144 (refer to FIG. 8 to be described later), but are not limited thereto.

As shown in FIG. 4 and FIG. 5, the transmission mechanism 144 includes a first transmission mechanism 144A and a second transmission mechanism 144B. The first transmission mechanism 144A causes the support part 120 to move in conjunction with the driving shaft 142, and moves the support part 120 between the forward position P1 and the backward position P2. The second transmission mechanism 144B causes the first restriction part 130A to move in conjunction with the driving shaft 142, and moves the first restriction part 130A between the forward position P1 and the backward position P2. In this manner, the first driving part 140A can simultaneously drive the first transmission mechanism 144A and the second transmission mechanism 144B by movement of the driving shaft 142 between the tip side and the base end side of the hand member 114, and accordingly drives movements of the support part 120 and the first restriction part 130A via the first transmission mechanism 144A and the second transmission mechanism 144B. Based on the above, since the support part 120 and the first restriction part 130A are driven by the transmission mechanism 144 driven by one common driving source 146, compared to the case where individual driving mechanisms and driving sources are provided for each of the support part 120 and the first restriction part 130A or for each of multiple support parts 120, the cost of the driving source and energy consumption can be reduced. Furthermore, by reducing the quantity of components of the robot hand 100, it is possible to miniaturize the robot hand 100 and the substrate conveyance apparatus 20 to which the substrate conveyance robot 30 including the robot hand 100 is attached.

As an example, the driving shaft 142 is connected to the first transmission mechanism 144A via a slider B1, and is connected to the second transmission mechanism 144B via a slider B2. When the driving shaft 142 moves to the tip side along the extending direction Y of the hand member 114, the driving shaft 142 moves the sliders B1 and B2 to the tip side along the extending direction Y, and accordingly, can simultaneously drive the first transmission mechanism 144A and the second transmission mechanism 144B, move the support part 120 and the first restriction part 130A to the forward position P1, and cause the support part 120 and the first restriction part 130A to protrude from the upper surface 114a of the hand member 114. In contrast, when the driving shaft 142 moves to the base end side along the extending direction Y of the hand member 114, the driving shaft 142 moves the sliders B1 and B2 to the base end side along the extending direction Y, and accordingly, can simultaneously drive the first transmission mechanism 144A and the second transmission mechanism 144B, move the support part 120 and the first restriction part 130A to the backward position P2, and retract the support part 120 and the first restriction part 130A into the recess 116 provided on the upper surface 114a of the hand member 114.

Accordingly, the robot hand 100 can adjust the positions of the support part 120 and the first restriction part 130A as necessary. For example, when the robot hand 100 is not in use for holding the substrate W, the support part 120 and the first restriction part 130A are integrally moved to the backward position P2 and accommodated in the recess 116, so the hand member 114 can be configured to be thin and can easily move to below the substrate W. When the robot hand 100 is in use for holding the substrate W, with the support part 120 and the first restriction part 130A integrally moving to the forward position P1, the substrate W can be held simultaneously by the support part 120 and the first restriction part 130A. Accordingly, the robot hand 100 can apply to holding a substrate W accommodated in a container with a narrow pitch.

In addition, the robot hand 100 further includes a holding unit 200 disposed at the hand member 114. The holding unit 200 includes a base part 210 disposed at the hand member 114, the first support part 120A as the support part 120, the first restriction part 130A as the restriction part 130, the first transmission mechanism 144A, and the second transmission mechanism 144B. The holding unit 200 is suitable for being attached to the hand member 114 of the robot hand 100, which has an upper surface (i.e., the upper surface 114a of the hand member 114) including the recess 116, to hold the substrate W, and, for example, is disposed at the hand member 114 and located in the recess 116. Herein, the first support part 120A is disposed on one side of the base part 210; the first restriction part 130A is disposed on another side of the base part 210 opposed to the first support part 120A; and the first support part 120A and the first restriction part 130A are arranged in parallel at positions opposed to each other across the driving shaft 142 of the first driving part 140A. In other words, the first transmission mechanism 144A to which the first support part 120A is connected, and the second transmission mechanism 144B to which the first restriction part 130A is connected, are arranged in parallel at positions opposed to each other across the driving shaft 142 which moves in an axial direction (i.e., an extending direction of the driving shaft 142, corresponding to the front-rear direction Y herein) by a driving force of the driving source 146. Herein, the base part 210 includes a driving shaft arrangement part R1. one arrangement part R2, and another arrangement part R3. The driving shaft 142 is arranged at the driving shaft arrangement part R1. The one arrangement part R2 is provided on one side of the driving shaft arrangement part R1, and the first transmission mechanism 144A is arranged at the one arrangement part R2. The another arrangement part R3 is provided on another side of the driving shaft arrangement part R1, and the second transmission mechanism 144B is arranged at the another arrangement part R3.

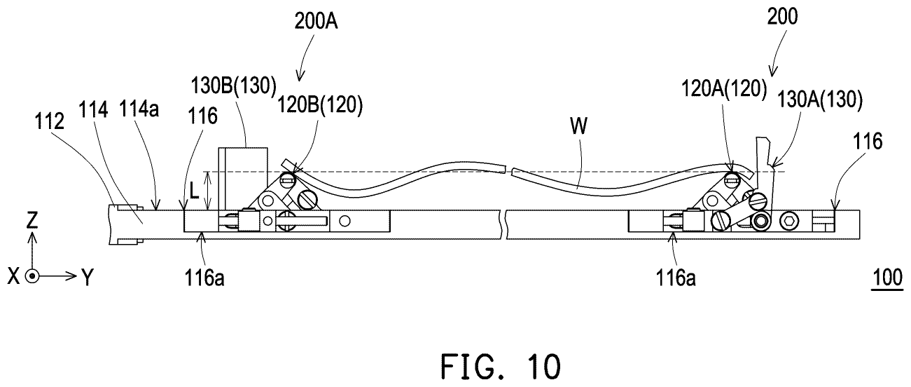

The base part 210 is disposed on a bottom surface 116a (refer to FIG. 10) of the recess 116 formed at the hand member 114, and has an accommodating opening 214 defined by a sidewall 212. The first support part 120A as the support part 120 is disposed at the base part 210 and supports the lower surface of the substrate W. The first transmission mechanism 144A is disposed at the base part 210 and connected to the first support part 120A. Similarly, the first restriction part 130A as the restriction part 130 is disposed at the base part 210 and is disposed to be opposed to or capable of abutting against the front end surface of the substrate W. The second transmission mechanism 144B is disposed at the base part 210 and connected to the first restriction part 130A as the restriction part 130. In other words, in this embodiment, the first support part 120A and the first restriction part 130A disposed adjacent to each other are disposed at the base part 210 and constitute the holding unit 200, and the transmission mechanism 144 described above (including the first transmission mechanism 144A and the second transmission mechanism 144B) is also disposed at the base part 210. Accordingly, the assembled holding unit 200 can be easily attached as one assembly to the recess 116 provided on the upper surface 114a of the hand member 114. Further, as an example, it is also possible that the robot hand 100 does not include the restriction part 130. In such an embodiment (a holding unit 200A to be described later), only the support part 120 and the transmission mechanism connected thereto are disposed at the base part 210.

The base part 210 is configured in a frame shape with the accommodating opening 214. and a thickness thereof (i.e., a size in the up-down direction Z) is smaller than a distance between the upper surface 114a of the hand member 114 and the bottom surface 116a of the recess 116. Accordingly, the base part 210 attached to the bottom surface 116a of the recess 116 is accommodated in the recess 116. Further, an upper surface 210a of the base part 210 attached to the bottom surface 116a of the recess 116 is lower than the upper surface 114a of the hand member 114. Further, the first support part 120A as the support part 120 is located in the accommodating opening 214 surrounded by the sidewall 212. Accordingly, when the first support part 120A is located at the backward position P2, the first support part 120A does not protrude from the upper surface 210a of the base part 210 and can be located at a position lower than the upper surface 114a of the hand member 114. Similarly, when the first restriction part 130A as the restriction part 130 is located at the backward position P2, the first restriction part 130A can also be located at a position lower than the upper surface 114a of the hand member 114. Accordingly, the robot hand 100 applying these holding units 200 can apply to holding a substrate W accommodated in a container with a narrow pitch. At the backward position P2, the positions of the support part 120 and the restriction part 130 may also protrude from the upper surface 210a of the base part 210 as long as they are located at positions lower than the upper surface 114a of the hand member 114.

The first transmission mechanism 144A drives the first support part 120A as the support part 120 by the driving force of the driving source 146, and moves the first support part 120A between a raising position (i.e., the forward position P1 shown in FIG. 4 and FIG. 6) higher than the upper surface 114a of the hand member 114 and capable of supporting the substrate W, and a lowering position (i.e., the backward position P2 shown in FIG. 5 and FIG. 7) lower than the upper surface 114a of the hand member 114. In another embodiment, the first transmission mechanism 144A may also drive the first support part 120A as the support part 120 by the driving force of the driving source 146, and move the first support part 120A between a raising position (i.e., the forward position P1 shown in FIG. 4 and FIG. 6) higher than the upper surface 210a of the base part 210 and capable of supporting the substrate W, and a lowering position (i.e., the backward position P2 shown in FIG. 5 and FIG. 7) lower than the raising position. Herein, the base part 210 is provided with a first guide hole O1 formed at the sidewall 212 and extending along the axial direction (i.e., the front-rear direction Y). The first transmission mechanism 144A includes a first linking member C1, a first driving member L1, and a second driving member L2. The first linking member C1 is, for example, a connecting pin, and the first driving member L1 and the second driving member L2 are, for example, linkages, but are not limited thereto. The first linking member C1 is inserted into the first guide hole O1 and connected to the driving shaft 142 which moves in the axial direction by the driving force of the driving source 146, and is capable of moving along the axial direction in the first guide hole O1. A first end E11 of the first driving member L1 is connected to the first linking member C1. A first end E21 of the second driving member L2 is rotatably disposed at the base part 210, and a second end E22 of the second driving member L2 is connected to the first driving member L1 in a relatively rotatable manner. Accordingly, the first support part 120A as the support part 120 moves between the raising position (i.e., the forward position P1 shown in FIG. 4 and FIG. 6) and the lowering position (i.e., the backward position P2 shown in FIG. 5 and FIG. 7) according to movement of the first linking member C1 in the axial direction (i.e., the front-rear direction Y) and conjunctive movement of the first driving member L1 and the second driving member L2.

In addition, the base part 210 is further provided with a second guide hole O2 formed at the sidewall 212 and extending along the axial direction (i.e., the front-rear direction Y). The first transmission mechanism 144A further includes a second linking member C2, a first driven member L3, a second driven member L4, and a connecting member C3. The second linking member C2 and the connecting member C3 are, for example, connecting pins, and the first driven member L3 and the second driven member L4 are, for example, linkages, but are not limited thereto. The second linking member C2 is inserted into the second guide hole O2 and is capable of moving along the axial direction in the second guide hole O2. A first end E31 of the first driven member L3 is connected to the second linking member C2. A first end E41 of the second driven member L4 is rotatably disposed at the base part 210, and a second end E42 of the second driven member L4 is connected to the first driven member L3 in a relatively rotatable manner. The connecting member C3 connects a second end E12 of the first driving member L1 and a second end E32 of the first driven member L3 in a relatively rotatable manner. Accordingly, the first support part 120A as the support part 120 corresponds to the connecting member C3, and moves between the raising position (i.e., the forward position P1 shown in FIG. 4 and FIG. 6) and the lowering position (i.e., the backward position P2 shown in FIG. 5 and FIG. 7) according to movement of the first linking member C1 in the axial direction (i.e., the front-rear direction Y) and conjunctive movement of the first driving member L1 and the second driving member L2. Also, the first driving member L1 causes the first driven member L3, the second driven member L4, and the second linking member C2 to move in conjunction by the connecting member C3.

Further, as shown in FIG. 4 and FIG. 6, the connecting member C3 has a bulging part 122 at a middle position in an axial direction thereof (i.e., the left-right direction X), and the bulging part 122 is capable of abutting against the lower surface of the substrate W as the support part 120 and supporting the lower surface of the substrate W. As an example, the bulging part 122 may be a tubular member rotatably fitted over the connecting pin serving as the connecting member C3. In the case of having a circular outer shape when viewed in the axial direction, since the tubular member is in line contact with the lower surface of the substrate W, the tubular member can support the substrate W with a minimized contact area; in the case of having a polygonal outer shape when viewed in the axial direction, since the tubular member is in surface contact with the lower surface of the substrate W, the tubular member can ensure a large holding force for the substrate W. Further, the tubular member is preferably formed of a material that is less likely to generate particles. For example, in the case of being formed of a polyurethane resin or the like having elasticity, by collapsing according to a weight of the substrate W, a contact region with the lower surface of the substrate W can be increased to further ensure a larger holding force for the substrate W. Further, in another embodiment (not shown), the bulging part 122 may be a portion integrally formed bulging from an outer circumferential surface of the connecting pin serving as the connecting member C3, or it is also possible that the bulging part 122 is not provided. The present invention is not limited thereto.

Further, the bottom surface 116a of the recess 116 includes a pin 116b protruding toward above the hand member 114. As shown in FIG. 4 and FIG. 5, the pin 116b is located in a movement region of the support part 120 moving in the up-down direction Z, and defines a position of the support part 120 at the backward position P2. By defining the position of the support part 120 at the backward position P2, the pin 116b restricts the first driving member L1 and the second driving member L2 constituting the first transmission mechanism 144A, and the first driven member L3 and the second driven member L4 from becoming horizontal with the axial direction of the driving shaft 142. As an example, the support part 120 located at the backward position P2 abuts against the pin 116b located lower than the support part 120, and is restricted from moving to be lower than the backward position P2 and becoming horizontal with the axial direction of the driving shaft 142. In other words, the first driving member L1 and the second driving member L2, and the first driven member L3 and the second driven member L4 located at the backward position P2 avoid aligning in a straight line shape horizontal with the axial direction of the driving shaft 142. Accordingly, due to the effect of the pin 116b, since a state in which the first driving member L1 and the second driving member L2, and the first driven member L3 and the second driven member L4 easily bend can be maintained, the support part 120 can reliably move from the backward position P2 toward the forward position P1. The pin 116b described above is provided on the bottom surface 116a of the recess 116 of the hand member 114, but in another embodiment (not shown), the pin 116b may also be integrally disposed with the base part 210. As an example, the base part 210 provides a bottom surface connected to the sidewall 212 below the sidewall 212, and the pin 116b described above is provided on this bottom surface to define the position of the support part 120 at the backward position P2. Further, a defining member that defines the position of the support part 120 is not limited to the pin 116b, and a shape and a position of the defining member may be adjusted as necessary.

The second transmission mechanism 144B drives the first restriction part 130A as the restriction part 130 by the driving force of the driving source 146, and moves the first restriction part 130A between a raising position (i.e., the forward position P1 shown in FIG. 4 and FIG. 6) that is higher than the upper surface 114a of the hand member 114 and is opposed to or capable of abutting against the front end surface of the substrate W, and a lowering position (i.e., the backward position P2 shown in FIG. 5 and FIG. 7) that is lower than the upper surface 114a of the hand member 114. In another embodiment, the second transmission mechanism 144B may drive the first restriction part 130A as the restriction part 130 by the driving force of the driving source 146, and move the first restriction part 130A between a raising position (i.e., the forward position P1 shown in FIG. 4 and FIG. 6) that is higher than the upper surface 210a of the base part 210 and is opposed to or capable of abutting against the front end surface of the substrate W, and a lowering position (i.e., the backward position P2 shown in FIG. 5 and FIG. 7) that is lower than the raising position. Herein, the base part 210 is provided with a third guide hole O3 formed at the sidewall 212 and extending along the axial direction (i.e., the front-rear direction Y). The second transmission mechanism 144B includes a third linking member C4, a third driving member L5, and a fourth driving member L6. The third driving member L5 serves as the first restriction part 130A, and a second end 52 of the third driving member L5 abuts against the front end surface of the substrate W. The third linking member C4 is, for example, a connecting pin, and the third driving member L5 and the fourth driving member L6 are, for example, linkages, but are not limited thereto. The third linking member C4 is inserted into the third guide hole O3 and connected to the driving shaft 142, and is capable of moving along the axial direction in the third guide hole O3. A first end E51 of the third driving member L5 is connected to the third linking member C4. A first end E61 of the fourth driving member L6 is rotatably disposed at the base part 210, and a second end E62 of the fourth driving member L6 is connected to the third driving member L5 in a relatively rotatable manner. Accordingly, the first restriction part 130A (the second end 52 of the third driving member L5) as the restriction part 130 moves between the raising position (i.e., the forward position P1 shown in FIG. 4 and FIG. 6) and the lowering position (i.e., the backward position P2 shown in FIG. 5 and FIG. 7) while undergoing a pivoting action centered on the first end E61 of the fourth driving member L6 rotatably disposed at the base part 210, according to movement of the third linking member C4 in the axial direction (i.e., the front-rear direction Y) and conjunctive movement of the third driving member L5 and the fourth driving member L6.

Further, the base part 210 includes a positioning member 220 extending from the sidewall 212 to the another arrangement part R3. As shown in FIG. 4 and FIG. 5, the positioning member 220 is located in a movement region of the first restriction part 130A moving in the up-down direction Z while undergoing a pivoting action, and defines the position of the first restriction part 130A at the backward position P2. By defining the position of the first restriction part 130A at the backward position P2, the positioning member 220 restricts the third driving member L5 and the fourth driving member L6 constituting the second transmission mechanism 144B from becoming horizontal with the axial direction of the driving shaft 142. As an example, the first restriction part 130A located at the backward position P2 abuts against the positioning member 220 located lower than the first restriction part 130A, and is restricted from moving to be lower than the backward position P2 and becoming horizontal with the axial direction of the driving shaft 142. In other words, the third driving member L5 and the fourth driving member L6 located in the backward position P2 avoid aligning in a straight line shape horizontal with the axial direction of the driving shaft 142. Accordingly, due to the effect of the positioning member 220, since the state in which the third driving member L5 and the fourth driving member L6 easily bend can be maintained, the first restriction part 130A can reliably move from the backward position P2 toward the forward position P1. The positioning member 220 described above is integrally disposed with the base part 210, but in another embodiment (not shown), the positioning member 220 may also be provided on the bottom surface 116a of the recess 116 of the hand member 114. As an example, a positioning member 220 protruding toward above the hand member 114 is provided on the bottom surface 116a of the recess 116 at a position close to an outer side of the another arrangement part R3 to define the position of the first restriction part 130A at the backward position P2. Further, the positioning member 220 defining the position of the first restriction part 130A is not limited to a block shape as shown, and a shape and a position of the positioning member 220 may be adjusted as necessary.

Based on the above, the first transmission mechanism 144A is provided with the first linking member C1, the first driving member L1, the second driving member L2, the second linking member C2, the first driven member L3, the second driven member L4, and the connecting member C3, takes the connecting member C3 as the support part 120, and is capable of moving the support part 120 between the raising position and the lowering position by a more stable action process. Specifically, the first transmission mechanism 144A takes the connecting member C3 as the first support part 120A and is capable of moving the first support part 120A between the forward position P1 and the backward position P2 by a more stable action process. Correspondingly, the second transmission mechanism 144B is provided with the third linking member C4, the third driving member L5, and the fourth driving member L6, takes the third driving member L5 as the restriction part 130, and is capable of moving the restriction part 130 between the raising position and the lowering position with a simpler structure. Specifically, the second transmission mechanism 144B takes the third driving member L5 as the first restriction part 130A and is capable of moving the first restriction part 130A between the forward position P1 and the backward position P2 with a simpler structure. However, in another embodiment (not shown), the same structure may be selected as the first transmission mechanism 144A and the second transmission mechanism 144B. For example, the second linking member C2, the first driven member L3, the second driven member L4, and the connecting member C3 may be omitted from the first transmission mechanism 144A, and the lower surface of the substrate W may be supported with the first driving member L1 as the support part 120 (first support part 120A). Alternatively, other structures (not shown) may be selected as the first transmission mechanism 144A and the second transmission mechanism 144B, and the present invention is not limited thereto.

In the above description, it has been described as an example that the first support part 120A as the support part 120 and the first restriction part 130A as the restriction part 130, which are disposed adjacent to each other, and the transmission mechanism 144 connected thereto (including the first transmission mechanism 144A and the second transmission mechanism 144B) are disposed at the base part 210 to serve as the holding unit 200. Herein, the driving shaft 142 of the first driving part 140A passes through the base part 210 and is connected to the first transmission mechanism 144A and the second transmission mechanism 144B by the corresponding sliders B1 and B2, etc. In this manner, the first support part 120A and the first restriction part 130A disposed adjacent to each other and the transmission mechanism 144 thereof can be easily attached to the hand member 114 as one assembly (i.e., the holding unit 200) (refer to FIG. 1), and the first support part 120A and the first restriction part 130A disposed as the holding unit 200 and attached can integrally move between the forward position P1 and the backward position P2 by driving of the driving shaft 142 of the first driving part 140A. In other words, in the robot hand 100, the support part 120 and the restriction part 130 can be attached according to a simpler method. Further, the robot hand 100 applying these holding units 200 can apply to holding a substrate W accommodated in a container with a narrow pitch.

Further, in this embodiment, although not disposed adjacent to the restriction part 130, the second support part 120B as the support part 120 may also be disposed at the base part 210 and attached as a holding unit 200A. As an example, as shown in FIG. 8, the holding unit 200A includes the base part 210, the second support part 120B as the support part 120, and the first transmission mechanism 144A. Accordingly, the holding unit 200A in FIG. 8 may be regarded as omitting a portion (another arrangement part R3) corresponding to the first restriction part 130A and the second transmission mechanism 144B of the holding unit 200 shown in FIG. 4 and FIG. 5, and by attaching such a holding unit 200A to the hand member 114 shown in FIG. 1, a second support part 120B as the support part 120 that is not disposed adjacent to the restriction part 130 is provided. In other words, the holding unit 200A can be easily attached as one assembly to the recess 116 provided on the upper surface 114a of the hand member 114. Accordingly, the support part 120 and the transmission mechanism 144 thereof can be disposed at the holding unit 200 or the holding unit 200A and easily attached to the hand member 114, and multiple support parts 120 disposed as the holding unit 200 or the holding unit 200A and attached can integrally move between the forward position P1 and the backward position P2 by driving of the driving shaft 142 of the first driving part 140A. In other words, in the robot hand 100, multiple support parts 120 can be attached according to a simpler method. Furthermore, the robot hand 100 applying these holding units 200 or holding units 200A can apply to holding a substrate W accommodated in a container with a narrow pitch. Similarly, the restriction part 130 disposed adjacent to the support part 120 can also be provided at the same base part 210 with the support part 120 and can be easily attached to the hand member 114 as the holding unit 200.

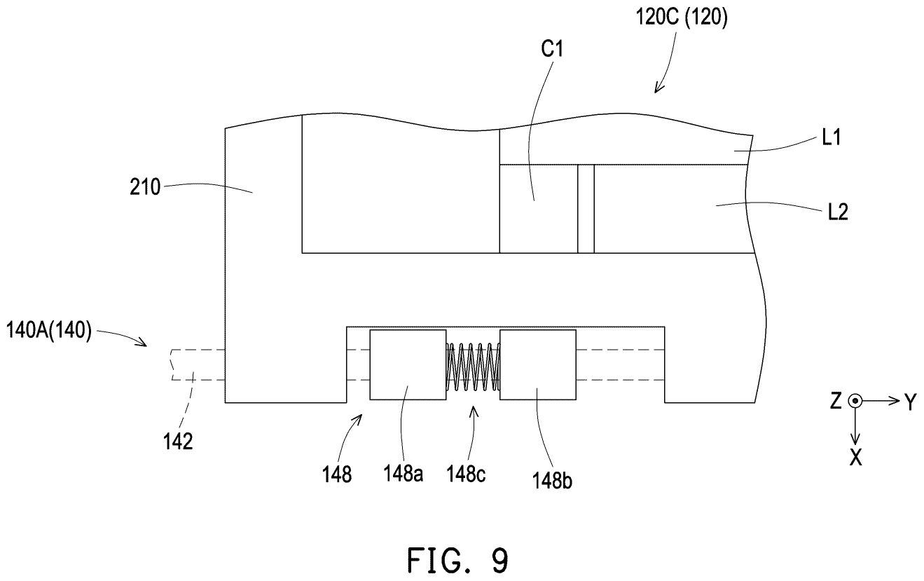

Further, the third support part 120C disposed between the first support part 120A and the second support part 120B may be disposed as the holding unit 200A which is not disposed adjacent to the restriction part 130, similar to the second support part 120B described above. Furthermore, as an example, the third support part 120C may be provided to be capable of protruding from the upper surface 114a of the hand member 114 by driving of the first driving part 140A, and retracting according to the weight of the substrate W held by the hand member 114. Specifically, as shown in FIG. 9, the first driving part 140A further includes a displacement support mechanism 148 capable of driving the third support part 120C to displace in a protruding and retracting direction. The displacement support mechanism 148 is, for example, provided at a portion of a region A of the holding unit 200A in FIG. 8, and has a moving member 148a, a linking member 148b, and an elastic member 148c. The moving member 148a is fixed to the driving shaft 142 and moves integrally with the driving shaft 142. The linking member 148b is capable of moving relatively with respect to the driving shaft 142 and is linked to the third support part 120C. As an example, the linking member 148b is linked to the first linking member C1 of the first transmission mechanism 144A connected to the third support part 120C, but is not limited thereto. The elastic member 148c is interposed between the moving member 148a and the linking member 148b.

Accordingly, the displacement support mechanism 148 displaces the third support part 130C between the forward position P1 and a position higher than the upper surface 114a of the hand member 114 according to the weight of the substrate W held by the hand member 114. Specifically, when the third support part 120C protrudes from the upper surface 114a of the hand member 114 toward the forward position P1 by driving of the first driving part 140A, the third support part 120C supporting the lower surface of the substrate W is pressed to be lower than the forward position P1 according to the weight of the substrate W held, and the linking member 148b linked to the first linking member C1 used by the third support part 120C moves with respect to the driving shaft 142, and approaches the moving member 148a while compressing the elastic member 148c. As a result, the third support part 120C retracts from the forward position P1 toward the upper surface 114a side of the hand member 114, and does not move to the forward position P1 as the first support part 120A and the second support part 120B do. Accordingly, since the third support part 120C supporting the substrate W at the middle position in the extending direction of the hand member 114 freely protrudes and retracts according to the weight of the substrate W, the substrate W held by the robot hand 100 can be supported in a more stable posture. Due to a spring force of the elastic member 148c or a width of the elastic member 148c itself, the third support part 120C does not move to be lower than the backward position P2. However, the present invention is not limited to using the displacement support mechanism 148 as a means for enabling moving the third support part 120C to retract according to the weight of the substrate W. nor is it limited to disposing the third support part 120C to be displaceable according to the weight of the substrate W.

Further, in another embodiment (not shown), the robot hand 100 is not limited to using the holding unit 200 or the holding unit 200A as described above. Specifically, the first support part 120A, the second support part 120B, and the third support part 120C as the support part 120, and the first restriction part 130A as the restriction part 130 may be directly attached to the recess 116 (refer to FIG. 1) on the upper surface 114a of the hand member 114, with the base part 210 omitted. Similarly, the driving shaft 142 of the first driving part 140A and the transmission mechanism 144 (including the first transmission mechanism 144A and the second transmission mechanism 144B) or other transmission mechanisms (not shown) may also be directly disposed at the hand member 114.

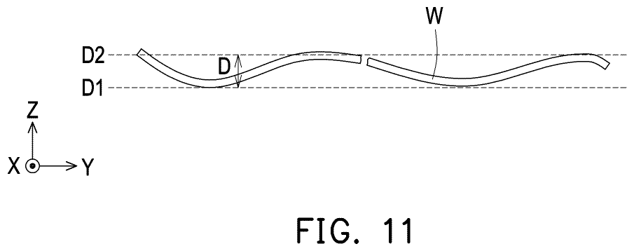

Furthermore, as shown in FIG. 10, the support part 120 of the robot hand 100 is preferably set assuming a state in which the support part 120 is located at the forward position P1 to hold a substrate W at which warpage occurs. Specifically, the first support part 120A, the second support part 120B, and the third support part 120C as the support part 120 are set to protrude to a position higher than a maximum warpage amount expected for the substrate W. Referring to FIG. 11, in the case of placing the substrate W on a virtual horizontal plane, the warpage amount of the substrate W refers to a plane spacing (distance D) between a virtual plane D1 parallel to the virtual horizontal plane at a site of the lower surface of the substrate W in contact with the virtual horizontal plane, and a virtual plane D2 parallel to the virtual horizontal plane at a site of the lower surface of the substrate W that is farthest from the virtual horizontal plane. Further, the maximum warpage amount expected for the substrate W refers to a maximum value of the plane spacing determined by the above definition, and is obtained by direct measurement of an actual substrate or calculation through simulation. The warpage amount of the substrate W does not necessarily need to be based on the state of being placed on the virtual horizontal plane, and, as an example, may also be obtained based on a state in which the substrate W is supported by the robot hand 100 or supported by a slot S of a container H to be described later. In that case, a plane equivalent to the virtual horizontal plane becomes the upper surface 114a of the hand member 114 (or the upper surface of the top cover 115), or a plane connecting the slot S.

Correspondingly, the support part 120 protrudes from the upper surface 114a of the hand member 114 (or the upper surface of the top cover 115) to a predetermined height (protruding amount L) to support the lower surface of the substrate W. Herein, the predetermined height (protruding amount L) is set to be larger than the maximum warpage amount expected for the substrate W. Accordingly, the forward position P1 of the support part 120 moving by driving of the first driving part 140A is set to a position that is away from the upper surface 114a of the hand member 114 (or the upper surface of the top cover 115) by more than the maximum warpage amount expected for the substrate W, i.e., set to a position higher than the expected warpage amount of the substrate W. As an example, a length (which may also be called the protruding amount L) of the support part 120 is set to be larger than the expected maximum warpage amount of the substrate W, and a contact point with the substrate W when the support part 120 is located at the forward position P1 is set to a position higher than the expected warpage amount of the substrate W. In other words, at the forward position P1, the support part 120 protrudes from the upper surface 114a of the hand member 114 (or the upper surface of the top cover 115), and the protruding amount L of the support part 120 is larger than the maximum warpage amount expected for the substrate W. For example, in the case where the maximum warpage amount of the substrate W is expected to be 6 mm, preferably, the forward position P1 of the support part 120 is set to be 6 mm or more from the upper surface 114a of the hand member 114, i.e., setting the protruding amount L of the support part 120 to be 6 mm or more. Thus, even if significant upward or downward warpage occurs at the substrate W (refer to FIG. 10), the support part 120 can support the substrate W with the lower surface of the substrate W and the upper surface 114a of the hand member 114 in a non-contact state. In other words, the lowest surface of the substrate W supported by the support part 120 is not in contact with the upper surface 114a of the hand member 114. Further, the warpage amount of the substrate W described herein includes deflection of the substrate W. As an example, a displacement of the substrate W due to expansion and contraction caused by thermal effects during a processing process of the substrate W is defined as warpage of the substrate W shown in FIG. 10, and a displacement in a gravity direction due to the weight and rigidity of the substrate W is defined as deflection of the substrate W. The above setting of the length (which may also be called the protruding amount L) of the support part 120 can accommodate the warpage amount of the substrate W including the deflection of the substrate W. In other words, the forward position P1 of the support part 120 is set to a position higher than the maximum warpage amount expected for the substrate W including the expected deflection amount of the substrate W. Accordingly, even if deflection occurs at the substrate W, the support part 120 can support the substrate W with the lower surface of the substrate W and the upper surface 114a of the hand member 114 in a non-contact state.

As shown in FIG. 3, the robot hand 100 is attached to the substrate conveyance robot 30, which conveys the substrate W, to hold the substrate W. The substrate conveyance robot 30 includes an arm part 32, a main body 34, a robot hand 100, and an arm driving part 36. The arm part 32 is attached to an upper end of the main body 34 in a manner capable of extending, retracting. and rotating within a horizontal plane (a virtual horizontal plane constituted by the left-right direction X and the front-rear direction Y) and also capable of rising and lowering in the up-down direction Z with respect to the main body 34. The robot hand 100 is attached to a tip of the arm part 32. The arm driving part 36 is, for example, a motor or a transmission mechanism built into the main body 34 and imparts a driving force to the arm part 32, but may also be attached to an outer side of the main body 34. Accordingly, the substrate conveyance robot 30 freely moves (raises, lowers, rotates, moves forward and backward) the robot hand 100 by driving the arm part 32 with the arm driving part 36.

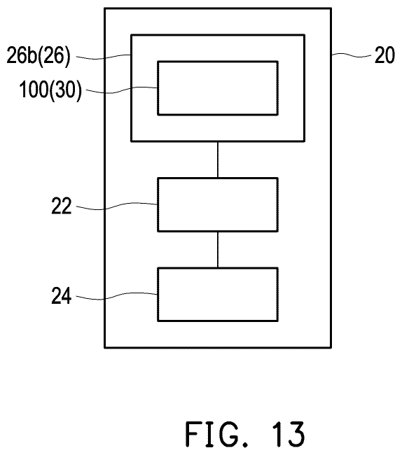

Further, as shown in FIG. 12 and FIG. 13, the substrate conveyance robot 30 is included in the substrate conveyance apparatus 20. As an example, the substrate conveyance apparatus 20 includes the substrate conveyance robot 30 including the robot hand 100, a detection part 22, a control part 24, and a substrate conveyance module 26 that accommodates therein the substrate conveyance robot 30. The substrate conveyance module 26 includes an EFEM 26a, the substrate conveyance robot 30 provided inside a casing of the EFEM 26a, a moving body 26b, and a guide structure 26c. The substrate conveyance robot 30 is attached to the moving body 26b. As an example, the main body 34 of the substrate conveyance robot 30 is attached to the moving body 26b and is disposed to be movable by the moving body 26b. The moving body 26b is attached to the guide structure 26c (e.g., a slide rail structure, a conveyor drive device, etc.) for guiding movement in the left-right direction X to configure the substrate conveyance robot 30 to be movable (slidable) in the left-right direction X. In addition, the substrate conveyance apparatus 20 further includes a frame structure 28 or the like for attaching members such as the moving body 26b and the guide structure 26c, but is not limited thereto.

The detection part 22 detects relative positions of the robot hand 100 and the substrate W. As shown in FIG. 1, a reflective sensor 118 provided on the tip side of the hand member 114 is used as the detection part 22. The reflective sensor 118 includes a light-emitting part that emits a detection light upward, and a light-receiving part that detects the detection light (hereinafter referred to as reflected light) reflected from the lower surface of the substrate W. In the case where the light-receiving part detects the reflected light, the reflective sensor 118 outputs an ON signal to the control part 24, and in the case where the light-receiving part does not detect the reflected light, the reflective sensor 118 outputs an OFF signal to the control part 24. Due to such characteristics, in the case where the hand member 114 is inserted below a substrate W supported by a slot S of a FOUP, which is an accommodating container for the substrate W, i.e., in the case where the hand member 114 is relatively moved in the front-rear direction Y with respect to the substrate W, the output of the reflective sensor 118 switches between the ON signal and the OFF signal at a timing of passing below the front end surface of the substrate W. In this embodiment, according to switching of the output between the ON signal and the OFF signal of the reflective sensor 118, the front end surface of the substrate W is detected (as shown in FIG. 1, detecting that the front end surface of the substrate W and the reflective sensor 118 serving as the detection part 22 are substantially aligned with each other). Further, an arrangement position of the reflective sensor 118 is set such that, in the case where the support part 120 is moved from the backward position P2 to the forward position P1 at the position at which the front end surface of the substrate W is detected, the support part 120 is opposed to an area on the lower surface of the substrate W where contact is allowed.

The control part 24 drives and integrally moves the support part 120 (e.g., the first support part 120A, and may further include the second support part 120B and the third support part 120C) and the first restriction part 130A. Furthermore, the control part 24 may drive and move the second restriction part 130B. The control part 24 is, for example, disposed on the substrate conveyance apparatus 20 and is electrically connected to the detection part 22 and the moving body 26b to which the substrate conveyance robot 30 is attached (refer to FIG. 13). Based on a detection result of the detection part 22, the control part 24 determines the position of the robot hand 100, starts control of the first driving part 140A (refer to FIG. 1, FIG. 4, and FIG. 5) of the robot hand 100, and integrally drives the support part 120 and the first restriction part 130A. Specifically, based on switching of the signal outputted from the reflective sensor 118 serving as the detection part 22 from the ON signal to the OFF signal, the control part 24 determines that the robot hand 100 inserted below the substrate W is located at a correct position, i.e., determining that the robot hand 100 is located at a position at which an area on the lower surface of the substrate W where contact is allowed and the support part 120 are opposed to each other in the case where the support part 120 is moved from the backward position P2 to the forward position P1, and the control part 24 starts driving the driving part 140. However, although the detection part 22 is the reflective sensor 118 provided on the tip side of the hand member 114, a type and a position of the detection part are not limited thereto and may be adjusted as necessary.

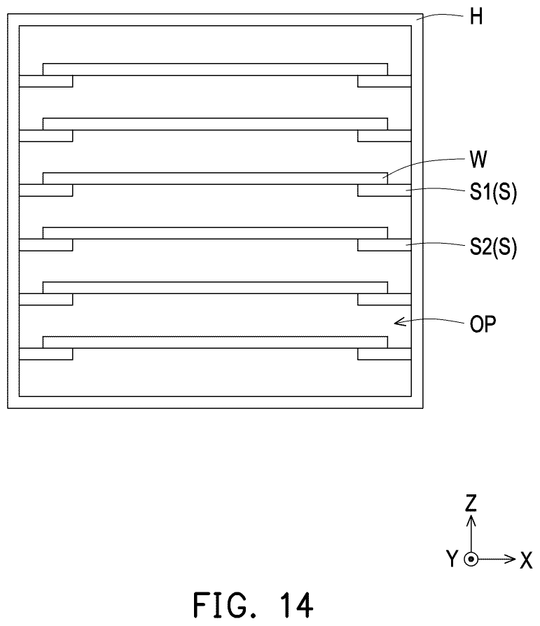

As shown in FIG. 12 and FIG. 14, the substrate W is, for example, a glass substrate used in PLP. and is accommodated in a FOUP, which is an accommodating container for the substrate W. The FOUP is, for example, a container H having 12 levels of placement shelves, stores the substrate W in each of the 12 levels of placement shelves, and accordingly, is capable of accommodating multiple substrates W. In this embodiment, it has been described as an example that 12 substrates W are stored in the FOUP, but the quantity of substrates W stored in the FOUP may be selected as appropriate (FIG. 14 shows a container H having 6 levels of slots S). Further, the FOUP as the container H includes a removal opening OP that serves as an opening for removing the substrate W, and multiple slots S that support the substrate W as a substrate support part. The slots S are provided in the container H accommodating multiple substrates W, partition multiple substrates W in the container H, and are composed of multiple partition plates arranged in parallel in the up-down direction.

Further, as shown in FIG. 12, multiple load ports 50 are connected to a front surface (left side in FIG. 12) of a casing outer wall of the EFEM 26a of the substrate conveyance module 26. Further, a processing apparatus 10 for processing the substrate W or a load lock chamber (not shown) is connected to a rear surface (right side in FIG. 12) of the casing outer wall of the EFEM 26a. The substrate conveyance robot 30 disposed inside the EFEM 26a is supported by the moving body 26b, and the moving body 26b is disposed to travel freely in the EFEM 26a by the guide structure 26c. Accordingly, the substrate conveyance robot 30 freely accesses any of the multiple load ports 50 and the processing apparatus 10 or the load lock chamber. Herein, the load port 50 is a device for opening and closing a door of the FOUP as the container H. The FOUP is placed at the load port 50. By opening the door of the FOUP at the load port 50, the substrate W stored in the FOUP faces a casing inner wall of the EFEM 26a, and transfer of the substrate W between the FOUP and the substrate conveyance robot 30 becomes possible. Then, the substrate conveyance robot 30 moves to a port door position of the load port 50 by the moving body 26b, and after moving the port door downward to open the door of the FOUP, the arm driving part 36 moves the arm part 32 such that the robot hand 100 moves to below the corresponding substrate W. Specifically, the robot hand 100 moves toward below the substrate W by an action of the arm part 32, holds the substrate W with the support part 120, and removes the corresponding substrate W from the FOUP as the container H.

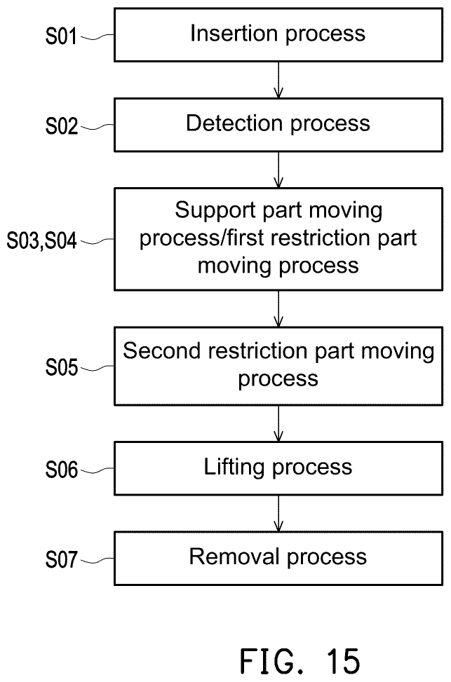

Referring to FIG. 15 to FIG. 19, the substrate removal method in this embodiment will be described. The substrate removal method is suitable for removing a substrate W supported by a slot S serving as the substrate support part in a FOUP serving as the container H, by the robot hand 100 provided at the substrate conveyance robot 30. The substrate removal method includes the following processes. Insertion process S01: Insert the hand member 114 of the robot hand 100 to below the substrate W. Detection process S02: Detect a position of the front end surface of the substrate W by the detection part 22 provided on the tip side of the hand member 114. Support part moving process S03: Move the support part 120 and support the lower surface of the substrate W. First restriction part moving process S04: Move the first restriction part 130A to be opposed to (or abut against) the front end surface of the substrate W. Second restriction part moving process S05: Move the second restriction part 130B to be opposed to (or abut against) the rear end surface of the substrate W. Lifting process S06: Raise the hand member 114 of the robot hand 100 inserted below the substrate W, and lift the substrate W from the slot S as the substrate support part by the support part 120 located at the forward position P1. Removal process S07: Move the hand member 114 of the robot hand 100 and remove the substrate W from the slot S as the substrate support part.

In more detail, in the insertion process S01, according to movement of the arm part 32 of the substrate conveyance robot 30 in the front-rear direction Y and the up-down direction Z, the hand member 114 of the robot hand 100 provided at the substrate conveyance robot 30 is inserted below the substrate W along an insertion direction (e.g., to the front side in the front-rear direction Y) facing the removal opening OP of the FOUP as the container H. In the insertion process S01, the hand member 114 of the robot hand 100 is inserted between an upper slot S1 and a lower slot S2 adjacent to each other among the multiple slots S, and the hand member 114 of the robot hand 100 is positioned below the substrate W supported by the upper slot S1. At this time, as shown in FIG. 16, the insertion process S01 is executed when the support part 120 and the first restriction part 130A are located at the backward position P2 lower than the upper surface 114a of the hand member 114. Furthermore, the insertion process S01 is executed when the second restriction part 130B is located at the retreat position P4 away from the substrate W, but the present invention is not limited thereto. Accordingly, the robot hand 100 is applied to holding a substrate W accommodated in a FOUP with a narrow pitch (distance between the upper slot S1 and the lower slot S2).

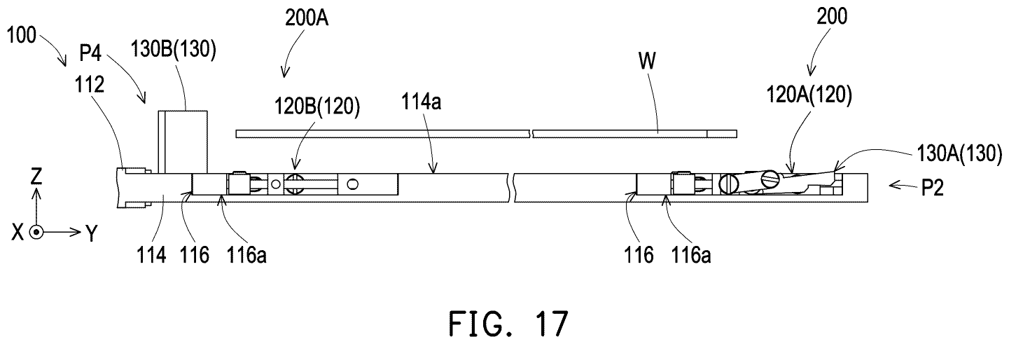

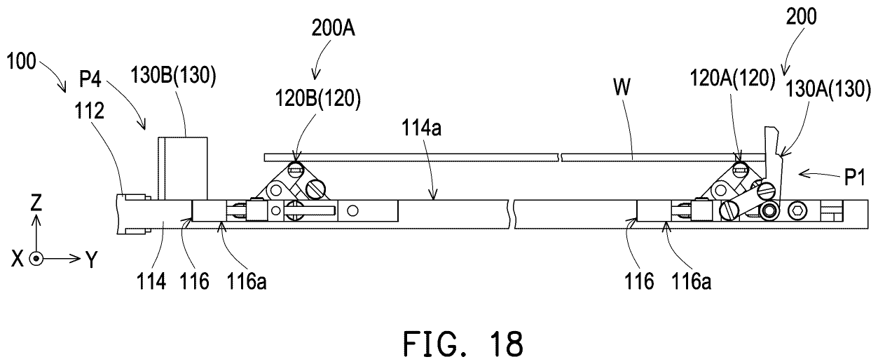

Next, in the detection process S02, the position of the front end surface of the substrate W supported by the upper slot S1 is detected by the reflective sensor 118 (refer to FIG. 1) as the detection part 22 provided on the tip side of the hand member 114. In the detection process S02, by moving, in the front-rear direction Y, the robot hand 100 inserted into the container H such that the signal outputted from the reflective sensor 118 to the control part 24 switches, the front end surface of the substrate W is detected, and the relative position of the robot hand 100 with respect to the substrate W is detected. Specifically, in the detection process S02, the robot hand 100 is moved toward a back side (to the front side in the front-rear direction Y) of the container H from the state in which the hand member 114 is located below the substrate W and the reflective sensor 118 outputs the ON signal. After the robot hand 100 moves past the front end surface of the substrate W to the back side of the container H and the reflective sensor 118 outputs the OFF signal, movement of the robot hand 100 is stopped, and the detection process S02 is completed. At this time point, as shown in FIG. 17, since the robot hand 100 itself is located below the substrate W, the support part 120 and the first restriction part 130A located at the backward position P2 do not touch the substrate W. The position at which the output of the reflective sensor 118 switches from the ON signal to the OFF signal is a state in which the robot hand 100 is located at the correct position with respect to the substrate W, and is a position at which the subsequent support part moving process S03 and the subsequent first restriction part moving process S04 may be executed.

The detection process S02 may also be executed simultaneously with the insertion process S01. In other words, in the insertion process S01, while inserting the hand member 114 to below the substrate W along the insertion direction (to the front side in the front-rear direction Y) facing the removal opening OP of the FOUP as the container H, as the detection process S02, an output change in the signal outputted from the reflective sensor 118 to the control part 24 may be monitored simultaneously. In that case, the insertion process S01 and the detection process S02 are executed until the output of the reflective sensor 118 switches from the ON signal to the OFF signal. The position at which the output of the reflective sensor 118 switches from the ON signal to the OFF signal is a state in which the robot hand 100 is located at the correct position with respect to the substrate W, and is a position at which the subsequent support part moving process S03 and the subsequent first restriction part moving process S04 may be executed.

Next, in the support part moving process S03, according to driving of the first driving part 140A, the support part 120 is moved from the backward position P2 to the forward position P1 which is set to a position higher than the upper surface 114a of the hand member 114 and away from the upper surface 114a of the hand member 114 by more than the maximum warpage amount expected for the substrate W. In the first restriction part moving process S04, according to driving of the first driving part 140A, the first restriction part 130A is moved from the backward position P2 to the forward position P1 located higher than the upper surface 114a of the hand member 114. Further, as shown in FIG. 18, the support part moving process S03 and the first restriction part moving process S04 are executed simultaneously according to driving of the first driving part 140A, i.e., the support part 120 and the first restriction part 130A are moved integrally. Herein, the support part 120 moved integrally with the first restriction part 130A may refer to the first support part 120A, or may refer to the three support parts 120, and the present invention is not limited thereto. In this manner, the robot hand 100 is applied to holding a substrate W accommodated in a FOUP with a narrow pitch. Further, the support part moving process S03 and the first restriction part moving process S04 may also be executed simultaneously by different driving parts, or may also be executed at different timings by the same first driving part 140A or different driving parts. Further, in an embodiment in which the first restriction part 130A is not provided, the first restriction part moving process S04 may be omitted, and the present invention is not limited thereto.

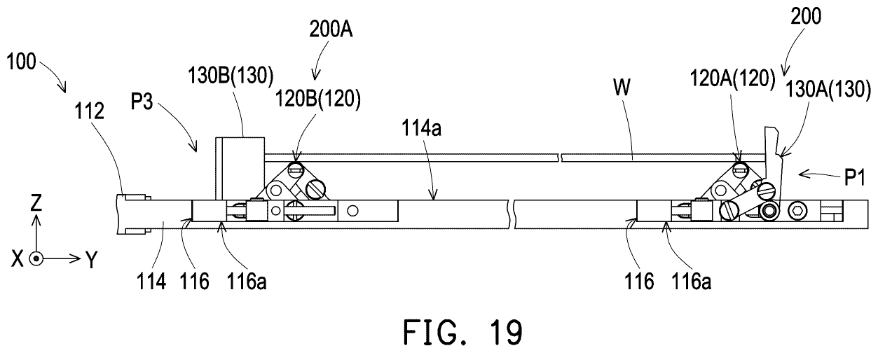

Next, in the second restriction part moving process S05, according to driving of the second driving part 140B, the second restriction part 130B is moved from the retreat position P4 which is away from the substrate W, to the advance position P3 which is closer to the substrate W than the retreat position P4. The second restriction part moving process S05 is executed between the support part moving process S03 and the first restriction part moving process S04, which are executed simultaneously, and the subsequent removal process S07. Furthermore, as shown in FIG. 19, in the second restriction part moving process S05, the second restriction part 130B moves from the retreat position P4 to the advance position P3 to press the substrate W to a position abutting against the first restriction part 130A. In this manner, since the first restriction part 130A and the second restriction part 130B can firmly abut against the front end surface and the rear end surface of the substrate W, holding stability of the substrate W is improved. Further, the first restriction part moving process S04 and the second restriction part moving process S05 may be executed simultaneously by different driving parts or the same first driving part. Further, in an embodiment in which the second restriction part 130B is not provided, the second restriction part moving process S05 may be omitted, and the present invention is not limited thereto.

Next, in the lifting process S06, the hand member 114 of the robot hand 100 inserted below the substrate W is raised (e.g., the arm part 32 is moved upward in the up-down direction Z), and the substrate W is lifted from the slot S (e.g., the upper slot S1 of the container H) by the support part 120 located at the forward position P1. The lifting process S06 is executed after execution of the insertion process S01 with the support part 120 and the first restriction part 130A located at the backward position P2, and execution of the support part moving process S03, the first restriction part moving process S04, and the second restriction part moving process S05 with the hand member 114 inserted below the substrate W, and before execution of the subsequent removal process S07. Accordingly, in a state shown in FIG. 19, since the substrate W is away from the upper slot S1 after the substrate W is lifted by the support part 120 located at the forward position P1 (i.e., the lifting process S06), subsequently, the removal process S07 can be executed to remove the substrate W from the container H.

Finally, in the removal process S07, the hand member 114 of the robot hand 100 is moved through the removal opening OP along a removal direction (e.g., to the rear side in the front-rear direction Y) away from the removal opening OP and opposite to the insertion direction, to remove the substrate W from the slot S serving as the substrate support part. For example, the arm part 32 moves to the rear side in the front-rear direction Y and removes the substrate W supported by the upper slot S1 from the upper slot S1. In the removal process S07, the substrate W is supported by the first support part 120A, the second support part 120B, and the third support part 120C, and is firmly clamped by the first restriction part 130A and the second restriction part 130B. Accordingly, the robot hand 100 can apply to holding a substrate W accommodated in a container H with a narrow pitch (i.e., the distance between the upper slot S1 and the lower slot S2) and configured to be thin. In another embodiment (not shown), it is also possible that the substrate W is not clamped by the first restriction part 130A and the second restriction part 130B in the removal process S07. In that case, the robot hand 100 suppresses fall-off of the substrate W during conveyance with a minimized contact area with the substrate W.

In summary, the robot hand of the present invention is capable of rising and lowering and is provided with the support part and the first restriction part, which are movable integrally, to hold a substrate, and accordingly, can apply to holding a substrate accommodated in a container with a narrow pitch and configured to be thin. Further, the substrate conveyance apparatus of the present invention is attached with the robot hand, and accordingly can apply to holding a substrate accommodated in a container with a narrow pitch and configured to be thin. Further, the holding unit of the present invention is provided with the support part capable of rising and lowering to hold a substrate, and accordingly is applied to handling a substrate accommodated in a container with a narrow pitch and configured to be thin and is easily attached to the robot hand. Furthermore, the substrate removal method of the present invention removes a substrate using the above robot hand, and accordingly can apply to holding a substrate accommodated in a container with a narrow pitch.

Finally, it should be noted that the above-described embodiments are used only to describe the technical solutions of the present invention and are not limited thereto. Although detailed descriptions of the present invention have been provided with reference to the above embodiments, it is naturally understood by those skilled in the art that the technical solutions described in the above embodiments may still be modified, or some or all of the technical features may be equivalently replaced. However, such modifications or replacements do not cause the essence of the corresponding technical solutions to deviate from the scope of the technical solutions of the embodiments of the present invention.

### INDUSTRIAL APPLICABILITY

The robot hand, the substrate conveyance apparatus, the holding unit, and the substrate removal method of the present invention are applied to handling a substrate accommodated in a container with a narrow pitch and configured to be thin, and are capable of addressing warpage occurring at the substrate.

### REFERENCE SIGNS LIST

10 Processing apparatus, 20 Substrate conveyance apparatus, 22 Detection part, 24 Control part, 26 Substrate conveyance module, 26a EFEM, 26b Moving body, 26c Guide structure, 28 Frame structure, 30 Substrate conveyance robot, 32 Arm part, 34 Main body, 36 Arm driving part, 50 Load port, 100 Robot hand, 112 Base, 114 Hand member, 114a Upper surface, 115 Top cover, 116 Recess, 116a Bottom surface, 116b Pin, 118 Reflective sensor, 120 Support part, 120A First support part. 120B Second support part, 120C Third support part, 122 Bulging part, 130 Restriction part, 130A First restriction part, 130B Second restriction part, 140 Driving part, 140A First driving part, 140B Second driving part, 142 Driving shaft, 144 Transmission mechanism, 144A First transmission mechanism, 144B Second transmission mechanism, 146 Driving source, 148 Displacement support mechanism, 148a Moving member, 148b Linking member, 148c Elastic member, 200, 200A Holding unit, 210 Base part. 210a Upper surface, 212 Sidewall, 214 Accommodating opening, 220 Positioning member, C1 First linking member, C2 Second linking member, C3 Connecting member, C4 Third linking member, D Distance, D1 Virtual plane, D2 Virtual plane, E11; E21; E31; E41; E51; E61 First end, E12; E22; E32; E42; E62 Second end, H Container, L Protruding amount, L1 First driving member, L2 Second driving member, L3 First driven member, L4 Second driven member, L5 Third driving member, L6 Fourth driving member, O1 First guide hole, O2 Second guide hole, O3 Third guide hole, OP Removal opening, P1 Forward position, P2 Backward position, P3 Advance position, P4 Retreat position, R1 Driving shaft arrangement part, R2 One arrangement part, R3 Another arrangement part, S Slot, S01 Insertion process, S02 Detection process, S03 Support part moving process, S04 First restriction part moving process, S05 Second restriction part moving process, S06 Lifting process, S07 Removal process, S1 Upper slot, S2 Lower slot, W Substrate.

1. A robot hand comprising:
a hand member holding a substrate;
a support part disposed at the hand member and supporting a lower surface of the substrate;
a first restriction part disposed on a tip side of the hand member and opposed to a front end surface of the substrate; and
a first driving part disposed at the hand member and driving the support part and the first restriction part, wherein
the first driving part integrally moves the support part and the first restriction part between a forward position higher than an upper surface of the hand member and a backward position lower than the forward position.

2. (canceled)

3. (canceled)

4. The robot hand according to claim 1, further comprising:
a second restriction part disposed on a base end side of the hand member and opposed to a rear end surface of the substrate.

5. (canceled)

6. The robot hand according to claim 1, wherein
the first driving part comprises:
a driving shaft moving between the tip side and the base end side of the hand member; and
a transmission mechanism causing the support part and the first restriction part to move in conjunction with the driving shaft, wherein
the transmission mechanism integrally moves the support part and the first restriction part between the forward position and the backward position.

7. The robot hand according to claim 6, wherein
the transmission mechanism comprises:
a first transmission mechanism that causes the support part to move in conjunction with the driving shaft and moves the support part between the forward position and the backward position; and
a second transmission mechanism that causes the first restriction part to move in conjunction with the driving shaft and moves the first restriction part between the forward position and the backward position.

8. (canceled)

9. (canceled)

10. The robot hand according to claim 1, further comprising:
a holding unit disposed at the hand member, wherein
the holding unit comprises a base part disposed at the hand member, the support part, and the first restriction part,
the support part is disposed on one side of the base part,
the first restriction part is disposed on another side of the base part opposed to the support part, and
the support part and the first restriction part are arranged in parallel at positions opposed to each other across a driving shaft of the first driving part.

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. A holding unit which is attached to a hand member of a robot hand having an upper surface provided with a recess and holds a substrate, the holding unit comprising:
a base part disposed in the recess of the hand member and having an accommodating opening defined by a sidewall; and
a support part disposed at the base part and supporting a lower surface of the substrate, wherein
a thickness of the base part is smaller than a depth of the recess, and
the support part is provided to be movable between a raising position higher than the upper surface of the hand member and a lowering position lower than the upper surface of the hand member.

25. The holding unit according to claim 24, further comprising:
a first transmission mechanism disposed at the base part and connected to the support part, wherein
the base part is configured in a frame shape with the accommodating opening,
the support part is located in the accommodating opening surrounded by the sidewall, and
the first transmission mechanism drives the support part by a driving force of a driving source to move the support part between a raising position higher than the upper surface of the hand member and a lowering position lower than the upper surface of the hand member.

26. The holding unit according to claim 25, wherein
the base part is provided with a first guide hole that is formed at the sidewall and extends along an axial direction,
the first transmission mechanism comprises:
a first linking member that is inserted into the first guide hole, is connected to a driving shaft moving in the axial direction by the driving force of the driving source, and is movable along the axial direction in the first guide hole;
a first driving member comprising a first end connected to the first linking member; and
a second driving member comprising a first end rotatably disposed at the base part and a second end connected to the first driving member in a relatively rotatable manner, and
the support part moves between the raising position and the lowering position according to movement of the first linking member in the axial direction and conjunctive movement of the first driving member and the second driving member.

27. The holding unit according to claim 26, wherein
the base part is further provided with a second guide hole that is formed at the sidewall and extends along the axial direction,
the first transmission mechanism further comprises:
a second linking member inserted into the second guide hole and movable along the axial direction in the second guide hole;
a first driven member comprising a first end connected to the second linking member;
a second driven member comprising a first end rotatably disposed at the base part and a second end connected to the first driven member in a relatively rotatable manner; and
a connecting member connecting the second end of the first driving member and a second end of the first driven member in a relatively rotatable manner, and
the support part corresponds to the connecting member, moves between the raising position and the lowering position according to movement of the first linking member in the axial direction and conjunctive movement of the first driving member and the second driving member, and the first driving member causes the first driven member, the second driven member, and the second linking member to move in conjunction by the connecting member.

28. The holding unit according to claim 25, further comprising:
a restriction part disposed at the base part and opposed to an end surface of the substrate; and
a second transmission mechanism disposed at the base part and connected to the restriction part, wherein
the second transmission mechanism moves the restriction part between the raising position and the lowering position by the driving force of the driving source.

29. The holding unit according to claim 28, wherein
the first transmission mechanism to which the support part is connected and the second transmission mechanism to which the restriction part is connected are arranged in parallel at positions opposed to each other across a driving shaft moving in the axial direction by the driving force of the driving source, and
the base part comprises:
a driving shaft arrangement part at which the driving shaft is arranged;
one arrangement part that is provided on one side of the driving shaft arrangement part and at which the first transmission mechanism is arranged; and
another arrangement part that is provided on another side of the driving shaft arrangement part and at which the second transmission mechanism is arranged.

30. A robot hand comprising:
a hand member having a holding unit according to claim 24 and being attached to the recess; and
a first transmission mechanism disposed at the base part and connected to the support part, wherein
the base part is configured in a frame shape with the accommodating opening,
the support part is located in the accommodating opening surrounded by the sidewall, and
the first transmission mechanism drives the support part by a driving force of a driving source to move the support part between a raising position higher than the upper surface of the hand member and a lowering position lower than the upper surface of the hand member.

31. A robot hand comprising:
a hand member holding a substrate;
a support part disposed at the hand member and supporting a lower surface of the substrate;
a first transmission mechanism disposed at the hand member and connected to the support part; and
a first driving part disposed at the hand member and driving the support part, wherein
the first transmission mechanism comprises:
a first linking member movable along an extending direction of the hand member;
a first driving member comprising a first end connected to the first linking member;
a second driving member comprising a first end rotatably disposed at the hand member and a second end connected to the first driving member in a relatively rotatable manner;
a second linking member movable along the extending direction of the hand member;
a first driven member comprising a first end connected to the second linking member;
a second driven member comprising a first end rotatably disposed at the hand member and a second end connected to the first driven member in a relatively rotatable manner; and
a connecting member connecting the second end of the first driving member and a second end of the first driven member in a relatively rotatable manner.

32. The robot hand according to claim 31, wherein
the first driving part drives the connecting member serving as the support part according to movement of the first linking member in the extending direction and conjunctive movement of the first driving member and the second driving member.

33. The robot hand according to claim 31, further comprising:
a defining member disposed at the hand member and defining a position of the support part, wherein
the support part is provided at a second end of the first driving member movably between a forward position and a backward position according to movement of the first linking member in the extending direction and conjunctive movement of the first driving member and the second driving member, and
the defining member defines the position of the support part located at the backward position.

34. The robot hand according to claim 31, comprising:
a base and the hand member extending from the base, wherein
the support part is a plurality of support parts disposed at the hand member and comprises:
a first support part disposed on the tip side of the hand member;
a second support part disposed on a base end side of the hand member; and
a third support part disposed between the first support part and the second support part in an extending direction of the hand member.

35. The robot hand according to claim 34, wherein
the first driving part further comprises a displacement support mechanism that drives the third support part to be displaceable in a protruding and retracting direction,
the displacement support mechanism comprises:
a moving member fixed to a driving shaft of the first driving part and moving integrally with the driving shaft;
a linking member that is capable of moving relatively with respect to the driving shaft and is linked to the third support part; and
an elastic member interposed between the moving member and the linking member, and
the displacement support mechanism displaces the third support part between the forward position and a position higher than the upper surface of the hand member according to a weight of the substrate held by the hand member.

36. The robot hand according to claim 31, wherein
the support part moves between the raising position and the lowering position according to movement of the first linking member in the extending direction and conjunctive movement of the first driving member and the second driving member.

37. A substrate conveyance apparatus comprising:
a substrate conveyance robot comprising the robot hand according claim 31;
a substrate conveyance module inside which the substrate conveyance robot is provided;
a detection part detecting relative positions between the robot hand and the substrate; and
a control part driving and moving the support part, wherein
based on a detection result of the detection part, the control part starts control of the first driving part of the robot hand to drive the support part.
